(19) United States
(12) Patent Application Publication
(10) Pub. No.: US 2008/0272487 A1
(43) Pub. Date: Nov. 6, 2008

(54) SYSTEM FOR IMPLEMENTING HARD-METAL WIRE BONDS

(76) Inventors: Il Kwon Shim, Singapore (SG); Hun Teak Lee, Ichon City (KR); Sheila Marie L. Alvarez, Singapore (SG); Gyung Sik Yun, Ichon si (KR); Heap Hoe Kuan, Singapore (SG)

Correspondence Address: LAW OFFICES OF MIKIO ISHIMARU, 333 W. EL CAMINO REAL, SUITE 330, SUNNYVALE, CA, 94087, US

(21) Appl. No.: 12/115,510

(22) Filed: May 5, 2008

Related U.S. Application Data
(60) Provisional application No. 60/916,272, filed on May 4, 2007.

(51) Int. Cl. H01L 23/49; H01L 21/44

(52) U.S. Cl. 257/737; 438/617; 257/E23.024; 257/E21.476

(57) ABSTRACT

A wire bond system including providing an integrated circuit die with a bond pad thereon, forming a soft bump on the bond pad, and wire bonding a hard-metal wire on the soft bump.

### CROSS-REFERENCE TO RELATED APPLICATION(S)

This application claims the benefit of U.S. Provisional Patent Application Ser. No. 60/916,272 filed on May 4, 2007.

### TECHNICAL FIELD

The present disclosure relates generally to semiconductor packaging technology, and more particularly to a system for creating bond wire connections using hard-metals.

### BACKGROUND ART

Micro devices and micro-circuits have come into use in a wide variety of consumer, commercial, industrial, and military devices and equipment. Micro-circuits, such as integrated circuits, contain a large number of active circuit elements, such as transistors, and passive elements, such as resistors and capacitors, mounted on a substrate. Semiconductor integrated circuits consist of small monolithic chips made of a semiconducting material, such as silicon, having discrete areas into which impurities are diffused to form circuit elements, and having conductive paths between circuit elements on the chip formed by conductive lines formed using diffused impurities or patterned metal layers. In hybrid micro-circuits, circuit elements mounted on a ceramic substrate are usually interconnected by conductive ink paths on the substrate.

Functional portions of integrated circuits are typically in the form of very small, rectangular-shaped chips. Electrical connections to integrated circuit chips are often made by wire bonding.

A wire bond is formed using ultrasonic energy and/or heat to form an inter-metallic bond or weld between a thin metal wire and a metalized area defined on a substrate. Such wire bonds are used to form interconnections between conductive pads of an integrated circuit chip and terminals of a package used to enclose and protect the chip. Bond wires and are also used to connect lead-out terminals to printed circuit boards.

Bond wires used to interconnect the pads of an integrated circuit chip to terminals of a package containing the chip are generally made of aluminum or gold, and have a diameter of about 1 mil (0.001 inch) or less. Each bond wire must be bonded to the upper surface of a small, typically rectangular-shaped, integrated circuit pad a few mils wide at one end of the wire to form a first bond site, and to another similarly shaped pad, or to a larger package terminal comprising a second bond site. In some cases, a length of bonding wire is interconnected to three or more pads, in a “daisy-chain” fashion referred to as stitch bonding.

The most common method of interconnecting wires between bond sites, such as integrated circuit chip pads and/or external terminals, uses ultrasonic energy to form a welded bond at each end of a conducting wire. To form such bonds, a free end of a length of bonding wire protruding from the tip of a tapered pencil-shaped bonding tool is placed in contact with a pad. The tool tip is then pressed against the wire, and energized with ultrasonic energy supplied by an ultrasonic transducer for a short time interval.

The combination of a vertically directed downward pressure applied by the tool to the contact region between the lower surface of the wire and the upper surface of the pad, combined with an oscillatory scrubbing motion at an ultrasonic frequency of the tool tip, in a horizontal direction parallel to the pad, causes an inter-molecular diffusion bond, sometimes referred to as a “weld,” to be formed between the wire and pad.

The automated tool is then moved in an arc-shaped path to another bond site. Motion of the tool tip away from a first, “source” bond site to a second “destination” bond site causes wire supplied from a supply reel or spool to an upper entrance opening of a wire feed bore through the tool, to be withdrawn from a lower exit opening of the bore and form an arch-shaped interconnecting wire segment between the first and second bond sites. The tool is then moved downwardly to press a trailing portion of the wire segment against the second bond site, and the ultrasonic transducer once again energized to bond the trailing end of the wire to the second bond site.

Often a wedge bond is made at the second bond site. The wedge bonder has a flat lower working face adapted to press a bonding wire into contact with a pad while ultrasonic energy is applied through the tool to the wire to form an ultrasonic weld. This working face is usually quite small, typically having a rectangular shape only about a few mils on a side, to permit bonding wire to small bond pads without contacting adjacent circuit elements.

After the second or last bond in a series of bonds has been thus formed, the wire is severed at the last bond site.

In view of the very small sizes of both the micro-circuit pads and bonding wire, it can be appreciated that ultrasonic bonding of connecting wires to integrated circuit pads or similar bond sites must be performed using an apparatus such as a bonding machine which permits the tool to be manipulated to precisely controllable positions within a coordinate space which encompasses a work area containing the small integrated circuit die.

Typical wire bonding machines used for ultrasonic welding of wires to micro-circuit pads include an elongated, generally cylindrically shaped force-applying member or “tool” which has a pointed lower end. The tool is usually vertically disposed, and has a shank mechanically coupled at an upper end thereof to a source of ultrasonic energy, such as a piezoelectric transducer, which is connected to an electrical energy source alternating at an ultrasonic frequency.

The integrated circuit chip is next environmentally sealed by use of a ceramic or an epoxy. Finally, the electrical leads that extend to the external portion of a package substrate or a lead frame are trimmed and prepared for connection to the package substrate or the printed circuit board so as to conduct electrical signals between the input and output terminals of the integrated circuit chip and the printed circuit board.

As the integrated circuit chip has become smaller and weaker ultra low dielectric constant dielectric materials become more common, the combination of the vertically directed downward static and acoustic pressure applied by the tool has been found to cause problems. The pressure squashes or crushes the contact pads resulting in distorting the pad resulting in poor wire bonding. This type of damage is exacerbated when harder metals, such as copper, are employed for the wire bonds. In some wire bonds, there is damage to the integrated circuit chip, which renders it inoperative. In other cases, the damage can induce displacement of the metal covering a bond pad, creating a “metal smear” that can short two contiguous bond pads.

Thus, a need still remains for a means for creating hard-metal wire bonds that minimize the potential for damage of the bond pads in an integrated circuit chip. In view of the ever-increasing commercial competitive pressures, along with growing consumer expectations and the diminishing opportunities for meaningful product differentiation in the marketplace, it is critical that answers be found for these problems. Additionally, the need to reduce costs, improve efficiencies and performance, and meet competitive pressures, adds an even greater urgency to the critical necessity for finding answers to these problems.

Solutions to these problems have been long sought but prior developments have not taught or suggested any solutions and, thus, solutions to these problems have long eluded those skilled in the art.

### DISCLOSURE OF THE INVENTION

The present invention provides a wire bond system including providing an integrated circuit die with a bond pad thereon, forming a soft bump on the bond pad, and wire bonding a hard-metal wire on the soft bump.

Certain embodiments of the invention have other aspects in addition to or in place of those mentioned above. The aspects will become apparent to those skilled in the art from a reading of the following detailed description when taken with reference to the accompanying drawings.

### BRIEF DESCRIPTION OF THE DRAWINGS

FIG. 1 (PRIOR ART) is a top view of a bond pad;

FIG. 2 (PRIOR ART) is a schematic cross-section of the bond pad along line 2-2 shown in FIG. 1;

FIG. 3 (PRIOR ART) is a top view of the bond pad of FIG. 1 following the formation of a hard-metal wire bond;

FIG. 4 (PRIOR ART) is a cross-section of the bond pad along line 4-4 of FIG. 3 following the formation of a hard-metal wire bond;

FIG. 5 (PRIOR ART) is a top view of the bond pad with the hard-metal wire bond in the proximity of a second bond pad following the placement of a second hard-metal wire bond on the second bond pad;

FIG. 6 (PRIOR ART) is a cross-section of the bond pad and the second bond pad along line 6-6 of FIG. 5 following the formation of a hard-metal wire bond and the second hard-metal wire bond;

FIG. 7 is a top view of the bond pad prior to the implementation of a hard-metal wire bond in an embodiment of the present invention;

FIG. 8 is a schematic cross-section of the of a bond pad along line 8-8 shown in FIG. 7;

FIG. 9 is a top view of the bond pad following the placement of a soft bump over portions of the metal pad layer in the bond pad;

FIG. 10 is a schematic cross-section of the of a bond pad along line 10-10 shown in FIG. 9 following the placement of the soft bump over portions of the metal pad layer in the bond pad;

FIG. 11 is a top view of the structure of FIG. 9 following the formation of a hard-metal wire bond over the soft bump (not shown);

FIG. 12 is a schematic cross-section of the structure of FIG. 11 along line 12-12;

FIG. 13 is a schematic drawing of a wire bonding machine and a bond tool at electronic flame off of a bond wire;

FIG. 14 is a schematic drawing of the wire bonding machine and bond tool as the tip of the bond wire is transformed into a wire ball;

FIG. 15 is a schematic drawing of the wire bonding machine and the bond tool at ultrasonic bonding on a bond pad in an integrated circuit die in accordance with an embodiment of the present invention;

FIG. 16 is a schematic drawing of the wire bonding machine and the bond tool of FIG. 15 at ultrasonic bonding of the hard-metal wire on the contact pad in the package substrate forming a wedge bond;

FIG. 17 is a schematic drawing of the wire bonding machine and the bond tool at ultrasonic bonding on the contact pad in the package substrate in accordance with an embodiment of the present invention;

FIG. 18 is a schematic drawing of the wire bonding machine and the bond tool of FIG. 17 at ultrasonic bonding of the hard-metal wire on the bond pad in the integrated circuit die forming the wedge wire bond over the soft bump;

FIG. 19 is a schematic drawing of the wire bonding machine and the bond tool at ultrasonic bonding of the hard-metal wire bond on the soft bump formed on the bond pad in the integrated circuit die in accordance with an embodiment of the present invention;

FIG. 20 is a schematic drawing of the wire bonding machine and the bond tool of FIG. 19 at ultrasonic bonding of the hard-metal wire on the contact pad in the package substrate forming the wedge wire bond over the second soft bump;

FIG. 21 is a schematic drawing of the wire bonding machine and the bond tool at ultrasonic bonding of the hard-metal wire bond on the second soft bump formed on the contact pad in the package substrate in accordance with an embodiment of the present invention;

FIG. 22 is a schematic drawing of the wire bonding machine and the bond tool of FIG. 21 at ultrasonic bonding of the hard-metal wire on the bond pad in the integrated circuit die forming the wedge wire bond over the soft bump; and

FIG. 23 is a flow chart of a system for a system for implementing hard-metal wire bonds in an embodiment of the present invention.

### BEST MODE FOR CARRYING OUT THE INVENTION

The following embodiments are described in sufficient detail to enable those skilled in the art to make and use the invention. It is to be understood that other embodiments would be evident based on the present disclosure, and that system, process, or mechanical changes may be made without departing from the scope of the present invention.

In the following description, numerous specific details are given to provide a thorough understanding of the invention. However, it will be apparent that the invention may be practiced without these specific details. In order to avoid obscuring the present invention, some well-known system configurations, and process steps are not disclosed in detail. Likewise, the drawings showing embodiments of the system are semi-diagrammatic and not to scale and, particularly, some of the dimensions are for the clarity of presentation and are shown greatly exaggerated in the drawing FIGs.

In addition, where multiple embodiments are disclosed and described having some features in common, for clarity and ease of illustration, description, and comprehension thereof, similar and like features one to another will ordinarily be described with like reference numerals.

For expository purposes, the term “horizontal” as used herein is defined as a plane parallel to the plane or surface of the bond pad, regardless of its orientation. The term “vertical” refers to a direction perpendicular to the horizontal as just defined. Terms, such as “above”, “below”, “bottom”, “top”, “side” (as in “sidewall”), “higher”, “lower”, “upper”, “over”, and “under”, are defined with respect to the horizontal plane. The term “on” means that there is direct contact among elements. The term “processing” as used herein includes deposition of material or photoresist, patterning, exposure, development, etching, cleaning, and/or removal of the material or photoresist as required in forming a described structure.

The term “system” as used herein refers to and is defined as the method and as the apparatus of the present invention in accordance with the context in which the term is used.

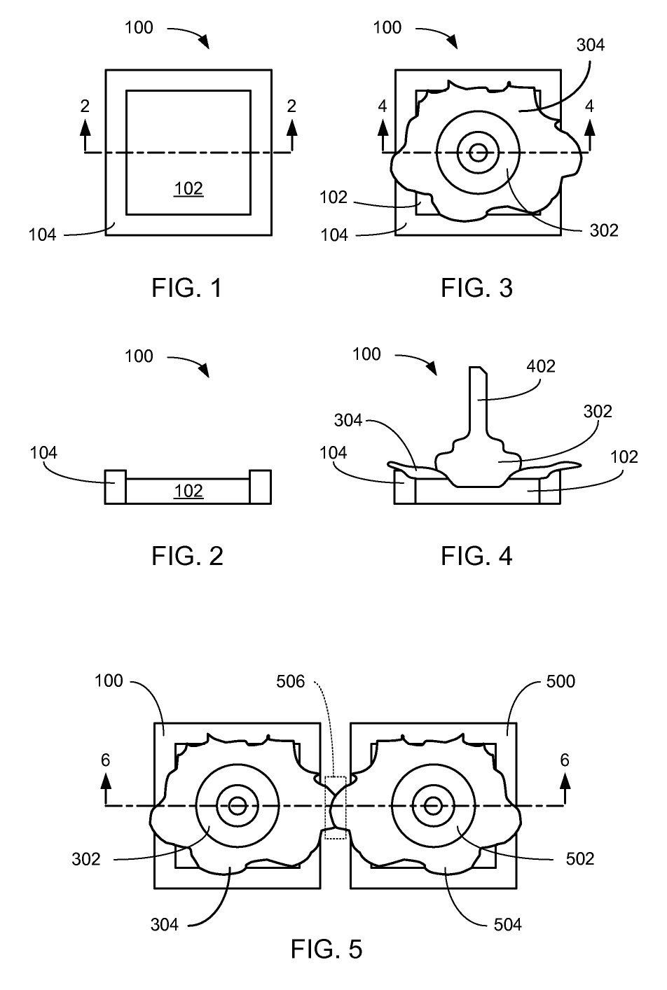

Referring now to FIG. 1 (PRIOR ART), therein is shown a top view of a bond pad 100. The bond pad 100 is formed by a metal pad layer 102 surrounded by the glassivation layer 104. The metal pad layer 102 may be aluminum, an aluminum alloy, or other metals that exhibit good metallurgy and low contact resistance. The glassivation layer 104 is the final passivation layer that is deposited on an integrated circuit chip. Typically the glassivation layer is composed of an amorphous material such as silicon oxide, silicon nitride, or a combination thereof.

Referring now to FIG. 2 (PRIOR ART), therein is shown a schematic cross-section of the bond pad 100 along line 2-2 shown in FIG. 1. The glassivation layer 104 is schematically shown as a ridge surrounding the metal pad layer 102. However, the bond pad 100 is formed by etching the glassivation layer 104 which is a conformal layer deposited over the entire integrated circuit chip (not shown).

Referring now to FIG. 3 (PRIOR ART), therein is shown a top view of the bond pad 100 of FIG. 1 following the formation of a hard-metal wire bond 302. As a result of the high acoustic energy and pressure needed to form the hard-metal wire bond 302, the metal pad layer 102 is displaced forming a metal smear 304 that extends over portions of the glassivation layer 104. Thus, the term “hard-metal” as used herein is defined as a material that requires sufficient acoustic energy to form a wire bond to cause detrimental deformation or damage of an element of an integrated circuit die or an element of a semiconductor package.

Referring now to FIG. 4 (PRIOR ART), therein is shown a cross-section of the bond pad 100 along line 4-4 of FIG. 3 following the formation of a hard-metal wire bond 302. The cross-section shows how the hard-metal wire bond 302 displaces material in the metal pad layer 102, forming the metal smear 304 that extends over portions of the metal pad layer 102 and the glassivation layer 104. The hard-metal wire bond 302 connects to a hard-metal wire 402.

Referring now to FIG. 5 (PRIOR ART), therein is shown a top view of the bond pad 100 with the hard-metal wire bond 302 in the proximity of a second bond pad 500 following the placement of a second hard-metal wire bond 502 on the second bond pad 500. As a result of the high acoustic energy and pressure needed to form the hard-metal wire bond 302 the metal smear 304 is formed. Similarly, a second metal smear 504 is formed on the second bond pad 500.

In cases where the bond pad 100 is in close proximity to the second bond pad 500, the metal smear 304 may contact the second metal smear 504, forming an electrical short 506. For expository purposes, the term “electrical short” as used herein is defined as the physical contact between two conductive materials, enabling the flow of electrons between the two materials.

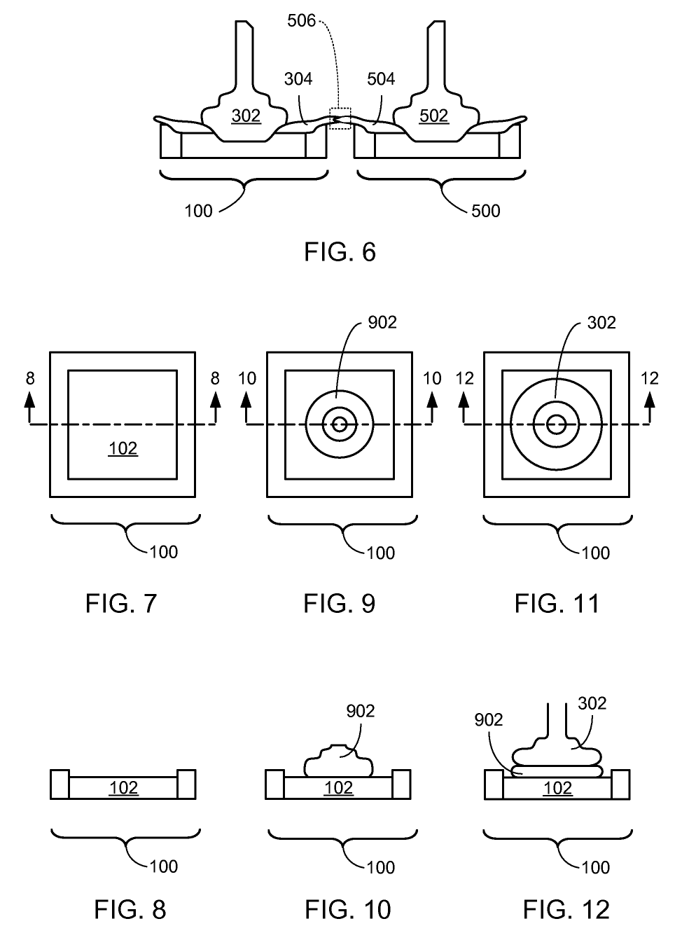

Referring now to FIG. 6 (PRIOR ART) therein is shown a cross-section of the bond pad 100 and the second bond pad 500 along line 6-6 of FIG. 5 following the formation of a hard-metal wire bond 302 and the second hard-metal wire bond 502. The metal smear 304 extends over the bond pad 100 forming the electrical short 506 as a result of making physical contact with the second metal smear 504 originating from the second bond pad 500.

Referring now to FIG.7 therein is shown a top view of the bond pad 100 prior to the implementation of a hard-metal wire bond 302 in an embodiment of the present invention. The bond pad 100 is formed by the metal pad layer 102 surrounded by the glassivation layer 104. The metal pad layer 102 may be aluminum, an aluminum alloy, or other metals that exhibit good metallurgy and low contact resistance. The glassivation layer 104 is the final passivation layer that is deposited on an integrated circuit chip. Typically the glassivation layer 104 is composed of an amorphous material such as silicon oxide, silicon nitride, or a combination thereof.

Referring now to FIG. 8, therein is shown a schematic cross-section of the of a bond pad 100 along line 8-8 shown in FIG. 7. The glassivation layer 104 is schematically shown as a ridge surrounding the metal pad layer 102. However, the bond pad 100 is formed by etching the glassivation layer 104 which is a conformal layer deposited over the entire integrated circuit chip (not shown).

Referring now to FIG.9 therein is shown a top view of the bond pad 100 following the placement of a soft bump 902 over portions of the metal pad layer 102 in the bond pad 100. The term “soft bump” as used herein is defined as a metal bump that is composed of a conductive material that can be formed on the bond pad 100 without significantly deforming the metal pad layer. In one embodiment of the invention the soft bump 902 is formed using a soft metal such as gold.

Referring now to FIG. 10, therein is shown a schematic cross-section of the of a bond pad 100 along line 10-10 shown in FIG. 9 following the placement of the soft bump 902 over portions of the metal pad layer 102 in the bond pad 100. The soft bump 902 is formed on the metal pad layer while eliminating or minimizing the formation of the metal smear 304 In the preferred embodiment of the invention the formation of the soft bump 902 does not induce significant deformation of the metal pad layer 102. It has been discovered that the formation of the soft bump 902 must occur under less than about 15 grams of vertical force.

Referring now to FIG. 11 therein is shown a top view of the structure of FIG. 9 following the formation of a hard-metal wire bond 302 over the soft bump 902 (not shown).

Referring now to FIG. 12, therein is shown a schematic cross-section of the structure of FIG. 11 along line 12-12. It has been unexpectedly discovered that the soft bump 902 absorbs or partially absorbs the high acoustic energy and pressure needed to form the hard-metal wire bond 302. Thus the formation of the hard-metal wire bond 302 induces deformation of the soft-bump 902, but does not significantly deform the metal pad layer.

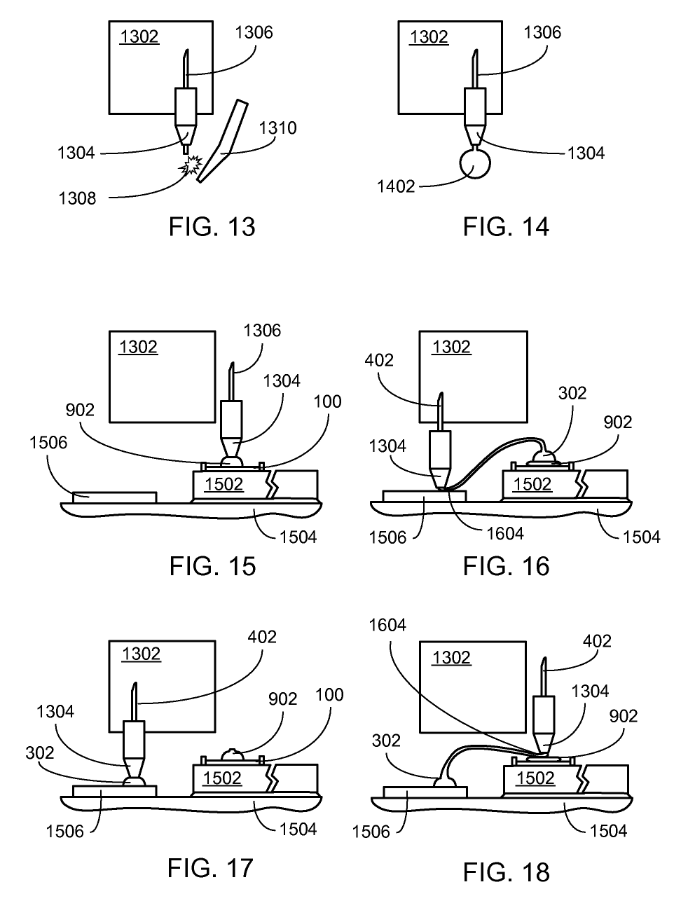

Referring now to FIG. 13, therein is shown a schematic drawing of a wire bonding machine 1302 and a bond tool 1304 at electronic flame off of a bond wire 1306. An electrical arc 1308 is generated between an arcing element 1310 and the bond tool 1304. The electrical arc 1308 generates heat that melts the bond wire 1306.

Referring now to FIG. 14, therein is shown a schematic drawing of the wire bonding machine 1302 and the bond tool 1304 as the tip of the bond wire 1306 is transformed into a wire ball 1402.

Referring now to FIG. 15, therein is shown a schematic drawing of the wire bonding machine 1302 and the bond tool 1304 at ultrasonic bonding on a bond pad 100 in an integrated circuit die 1502 in accordance with an embodiment of the present invention. The integrated circuit die 1502 is mounted on a package substrate 1504 with a contact pad 1506 which may be connected to other active or passive elements in the package substrate 1504. The bond tool 1304 is pressing the wire ball 1402 against the bond pad 100, forming the soft bump 902.

Referring now to FIG. 16, therein is shown a schematic drawing of the wire bonding machine 1302 and the bond tool 1304 of FIG. 15 at ultrasonic bonding of the hard-metal wire 402 on the contact pad 1506 in the package substrate 1504 forming a wedge wire bond 1604. The hard-metal wire bond 302 is formed on top of the soft bump 902, which absorbs the pressure and ultrasonic energy generated by the bond tool 1304.

The embodiment of the invention schematically shown in FIG. 15 and FIG. 16 is a means to connect the integrated circuit die 1502 to the package substrate 1504 using the soft bump 902 and the hard-metal wire bond 302 on the bond pad 100 in the integrated circuit die 1502 and the wedge wire bond 1604 on the contact pad 1506 in the package substrate 1504. This embodiment of the invention is especially suitable when the contact pad 1506 in the package substrate 1504 is resistant to the acoustic energy and pressure used in the ultrasonic bonding process.

Referring now to FIG. 17, therein is shown a schematic drawing of the wire bonding machine 1302 and the bond tool 1304 at ultrasonic bonding on the contact pad 1506 in the package substrate 1504 in accordance with an embodiment of the present invention. The bond tool 1304 has already formed the soft bump 902 on the bond pad 100 in the integrated circuit die 1502. The hard-metal wire bond 302 is being formed on the contact pad 1506 in the package substrate 1504 using the hard-metal wire 402.

Referring now to FIG. 18, therein is shown a schematic drawing of the wire bonding machine 1302 and the bond tool 1304 of FIG. 17 at ultrasonic bonding of the hard-metal wire 402 on the bond pad 100 in the integrated circuit die 1502 forming the wedge wire bond 1604 over the soft bump 902.

The embodiment of the invention schematically shown in FIG. 17 and FIG. 18 is a means to connect the integrated circuit die 1502 to the package substrate 1504 using the soft bump 902 and the wedge wire bond 1604 on the bond pad 100 in the integrated circuit die 1502 and the hard-metal wire bond 302 directly on the contact pad 1506 in the package substrate 1504.

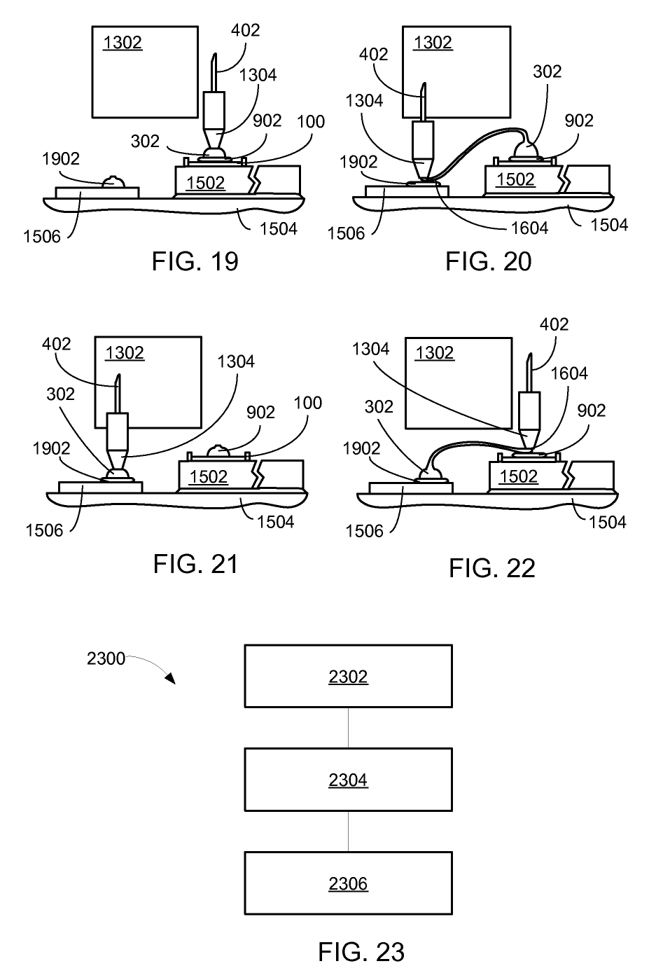

Referring now to FIG. 19, therein is shown a schematic drawing of the wire bonding machine 1302 and the bond tool 1304 at ultrasonic bonding of the hard-metal wire bond 302 on the soft bump 902 formed on the bond pad 100 in the integrated circuit die 1502 in accordance with an embodiment of the present invention. A second soft bump 1902 is formed on the contact pad 1506 in the package substrate 1504.

Referring now to FIG. 20, therein is shown a schematic drawing of the wire bonding machine 1302 and the bond tool 1304 of FIG. 19 at ultrasonic bonding of the hard-metal wire 402 on the contact pad 1506 in the package substrate 1504 forming the wedge wire bond 1604 over the second soft bump 1902.

The embodiment of the invention schematically shown in FIG. 19 and FIG. 20 is a means to connect the integrated circuit die 1502 to the package substrate 1504 using the soft bump 902 and the hard-metal wire bond 302 on the bond pad 100 in the integrated circuit die 1502 and the second soft bump 1902 and the wedge wire bond 1604 on the contact pad 1506 in the package substrate 1504.

Referring now to FIG. 21, therein is shown a schematic drawing of the wire bonding machine 1302 and the bond tool 1304 at ultrasonic bonding of the hard-metal wire bond 302 on the second soft bump 1902 formed on the contact pad 1506 in the package substrate 1504 in accordance with an embodiment of the present invention. The soft bump 902 is formed on the bond pad 100 in the integrated circuit die 1502.

Referring now to FIG. 22, therein is shown a schematic drawing of the wire bonding machine 1302 and the bond tool 1304 of FIG. 21 at ultrasonic bonding of the hard-metal wire 402 on the bond pad 100 in the integrated circuit die 1502 forming the wedge wire bond 1604 over the soft bump 902.

The embodiment of the invention schematically shown in FIG. 21 and FIG. 22 is a means to connect the integrated circuit die 1502 to the package substrate 1504 using the second soft bump 1902 and the hard-metal wire bond 302 on the contact pad 1506 in the package substrate 1504 and the soft bump 902 and the wedge wire bond 1604 on the bond pad 100 in the integrated circuit die 1502.

It has been discovered that the embodiments using the soft bump for stitch or wedge bonds are especially advantageous because the soft bump acts as a type of additional encompassing solder for these bonds where the hard-metal wire is directly bonded without forming a mound of metal.

Referring now to FIG. 23, therein is shown a flow chart of a system 2300 for a system for implementing hard-metal wire bonds in an embodiment of the present invention. The system 2300 includes providing an integrated circuit die with a bond pad thereon in a block 2302; forming a soft bump on the bond pad in a block 2304; and wire bonding a hard-metal wire on the soft bump in a block 2306.

The resulting processes and configurations are straightforward, cost-effective, uncomplicated, highly versatile, accurate, sensitive, and effective, and can be implemented by adapting known components for ready, efficient, and economical manufacturing, application, and utilization.

While the invention has been described in conjunction with a specific best mode, it is to be understood that many alternatives, modifications, and variations will be apparent to those skilled in the art in light of the aforegoing description. Accordingly, it is intended to embrace all such alternatives, modifications, and variations that fall within the scope of the included claims. All matters hithertofore set forth herein or shown in the accompanying drawings are to be interpreted in an illustrative and non-limiting sense.

What is claimed is:

1. A wire bond system comprising:
providing an integrated circuit die with a bond pad thereon;
forming a soft bump on the bond pad; and
wire bonding a hard-metal wire on the soft bump.

2. The system as claimed in claim 1 further comprising:
providing a package substrate with a contact pad thereon;
forming a second soft bump on the contact pad; and
wire bonding the hard-metal wire on the second soft bump.

3. The system as claimed in claim 1 further comprising:
providing a package substrate with a contact pad thereon; and
wire bonding the hard-metal wire on the contact pad.

4. The system as claimed in claim 1 wherein wire bonding of the hard-metal wire on the soft bump is performed using a hard-metal wire bond.

5. The system as claimed in claim 1 wherein wire bonding of the hard-metal wire on the soft bump is performed using a wedge wire bond.

6. A wire bond system comprising:
providing an integrated circuit die with a bond pad thereon;
providing a package substrate with a contact pad thereon;
forming a soft bump on the bond pad; and
wire bonding a hard-metal wire from the soft bump to the contact pad.

7. The system as claimed in claim 6 further comprising:
forming a second soft bump on the contact pad; and
wherein:
wire bonding the hard-metal wire is performed from the soft bump to the second soft bump.

8. The system as claimed in claim 6 wherein wire bonding of the hard-metal wire on the soft bump is performed using a hard-metal wire bond.

9. The system as claimed in claim 6 wherein wire bonding of the hard-metal wire on the second soft bump is performed using a hard-metal wire bond.

10. The system as claimed in claim 6 wherein wire bonding of the hard-metal wire on the second soft bump is performed using a wedge wire bond.

11. A wire bond system comprising:
an integrated circuit die with a bond pad thereon;
a soft bump located on the bond pad; and
a hard-metal wire wire bonded on the soft bump.

12. The system as claimed in claim 11 further comprising:
a package substrate with a contact pad thereon;
a second soft bump on the contact pad; and
the hard-metal wire wire bonded on the second soft bump.

13. The system as claimed in claim 11 further comprising:
a package substrate with a contact pad thereon; and
the hard-metal wire wire bonded on the contact pad.

14. The system as claimed in claim 11 wherein a hard-metal wire bond connects the soft bump to the hard-metal wire.

15. The system as claimed in claim 11 wherein a wedge wire bond connects the soft bump to the hard-metal wire.

16. The system as claimed in claim 11 further comprising:
a package substrate with a contact pad thereon; and
the hard-metal wire wire bonded to the contact pad.

17. The system as claimed in claim 16 further comprising:
a second soft bump on the contact pad; and
wherein:
the hard-metal wire is wire bonded to the second soft bump.

18. The system as claimed in claim 16 wherein a hard-metal wire bond connects the hard-metal wire to the soft bump.

19. The system as claimed in claim 16 wherein a hard-metal wire bond connects the hard-metal wire to the second soft bump.

20. The system as claimed in claim 16 wherein a wedge wire bond connects the hard-metal wire to the second soft bump.
